(19) United States
(12) Patent Application Publication
(10) Pub. No.: US 2007/0205102 A1
(43) Pub. Date: Sep. 6, 2007

(54) SUPPORT PLATE FOR SPUTTER TARGETS

(75) Inventors: Roland Scholl, Gorwihl (DE); Bernd Meyer, Laufenburg (DE); Gerd Passing, Hurth (DE); Gerhard Wotting, Coburg (DE)

Correspondence Address: CONNOLLY BOVE LODGE & HUTZ, LLP, P O BOX 2207, WILMINGTON, DE, 19899, US

(73) Assignee: H. C. Starck GmbH & Co. KG, Goslar (DE)

(21) Appl. No.: 11/568,218

(22) PCT Filed: Apr. 9, 2005
(86) PCT No.: PCT/EP05/03757

§ 371 Date: Mar. 28, 2007

(30) Foreign Application Priority Data
Apr. 23, 2004 (DE) 10 2004 020 404.7

(51) Int. Cl. C23C 14/00

(52) U.S. Cl. 204/298.12

(57) ABSTRACT

Backing plate for sputter targets made of a composite material which comprises 5 to 99 wt. % of at least one refractory metal from the group consisting of Mo, W, Re and Ta and 95 to 1 wt. % of at least one fuirther metallic component from the group consisting of Cu, Ag and Au, process for the production thereof and unit which comprises the backing plate and a sputter target.

The invention relates to a backing plate for sputter targets, wherein the backing plate is made of a composite material which comprises at least one refractory metal and at least one further metallic component from the group consisting of Cu, Ag and Au, a process for the production of such a backing plate and units which comprise the backing plate and a sputter target.

Materials in the most general sense are distinguished by inherent physical properties for which a theoretical description is often difficult and which—as natural limit values—cannot be “improved” by technical artifices. A material frequently also has one or more undesirable properties in addition to one desired for a particular technical use.

In addition to the physical properties of the materials, such as thermal conductivity (TC), linear coefficient of thermal expansion (CTE) and elasticity modulus (E modulus), technical/technological properties, such as producibility, workability and costs, are also of decisive importance for various uses.

High thermal conductivities are achieved on pure metals (Ag, Au, Cu, W, Mo, . . . ). Low contents (01 to 3 at. %) of impurities often lead here to a dramatic drop in thermal conductivity. The cause of this is, for example, a formation of mixed crystals and the formation of intermetallic compounds or of second phases.

To a first approximation, the CTE is inversely proportional to the melting temperature (Tₘ) of the metal. The so-called refractory metals (W, Mo, Re, Ta, Ru) with a high Tₘ of between 3,700 K (W) and 2,600 K (Ru) are thus possible for uses where a very low CTE is desired (W: 4.7×10⁻⁶/K to Ta: 6.8×10⁻⁶/K) The most essential properties of refractory metals and metals of high thermal conductivity are summarized in Table 1.

TABLE 1
“Properties of refractory metals and metals of high
thermal conductivity” [Source: FAPP: F.S Microware,
Inc. 2234 Wade Court, Hamilton, OH 45013]

| | CTE | TC | E modulus | Density | Tₘ¹ |
|---|---|---|---|---|---|
| Element | 10⁻⁶/K | W/mK | GPa | g/cm³ | K |
| Ag | 16.5 | 425 | 71 | 10.5 | 1,230 |
| Au | 13.9 | 317 | 78 | 19.3 | 1,340 |
| Cu | 16.8 | 400 | 131 | 8.96 | 1,360 |
| W | 4.7 | 174 | 410 | 19.3 | 3,700 |
| Mo | 5.2 | 138 | 318 | 10.2 | 2,900 |
| Re | 6.2 | 48 | 460 | 21 | 3,500 |
| Ta | 6.8 | 57 | 185 | 16.7 | 3,300 |
| Ru | 5.3 | 117 | — | 12.4 | 2,600 |
| Zr | 5.2 | 22.7 | 84 | 6.5 | 2,100 |
| Be | 11.6 | 200 | 303 | 18.5 | 1,500 |
| Ni | 13.9 | — | 207 | 8.9 | 1,700 |
| Pb | 28.7 | 35 | 24 | 11.4 | 600 |

¹Tₘ = melting temperature
—: no data available

To a first approximation, the E modulus of pure metals also correlates with the melting temperature. High E moduli, such as, for example, W, Mo, Re and Ta have, lead to the corresponding metals being workable only with difficulty.

The production of metallic materials and components of high thermal conductivity can be carried out via melting metallurgy. However, there are commercial and technical limits when the melting temperatures of the metals to be processed are above approx. 2,000 K. Components of metals of higher melting temperatures, such as, for example, W, Mo, Re or Ta, are therefore preferably produced via powder metallurgy processes. This lead to high production costs (material price, technology costs, workability).

In principle, powder metallurgy offers the possibility of producing components of complicated shape from metallic materials of largely any desired composition. It is thus possible in principle, for example, to process the metals shown in Table 1 and/or mixtures of these metals to desired material combinations by powder metallurgy.

Corresponding materials can also be produced by a combination of powder metallurgy and melting metallurgy process steps, for example by so-called infiltration methods. However, it is to be noted here that the desired functional properties of the material formed, e.g. the thermal conductivity, should not be adversely influenced by metallurgical effects, for example reactions due to the formation of intermetallic phases, of mixed crystals or of other foreign phases, which in each case lead to a significant lowering of the thermal conductivity.

By the routes described, it is possible to produce so-called composite materials which comprise components having a low linear coefficient of thermal expansion and a moderate thermal conductivity, for example W, Mo, Re or Ta, and components having a very high thermal conductivity and a high linear coefficient of thermal expansion, for example Cu, Ag or Au. A material having a relatively high TC (>200 W/m*K) at a comparatively low coefficient of thermal expansion is formed in this manner. These materials moreover can also be readily worked by machining, in contrast to pure refractory metals.

However, the involved production of components by the infiltration process, which as a rule comprises two thermal processes at a high temperature (sintering of a skeleton body T: >1,600° C., infiltration of the porous body with Cu, T: >1,200° C.) is a disadvantage. Involved mechanical working is then necessary in order to achieve the exact connection dimensions. If it is possible to produce a porous shaped body from a refractory metal by powder metallurgy processes, a one-stage production of a composite material can also be achieved by carrying out the infiltration directly in a thermal step together with the compaction.

For uses where materials of particularly low linear coefficient of thermal expansion and only moderate thermal conductivity are required, materials of refractory metals (W, Mo, Re, Ta, . . . ) without further additives are possible. In addition to the high material costs and the difficult production of dense components (hot forming processes), an involved mechanical precision working is moreover necessary.

Typical uses where materials of high thermal conductivity and adjustable linear coefficient of thermal expansion are required are beat sinks. A distinction may be made between two essential fields of use:
(1) Components having a maximum dimension in one direction of up to approx. 5 cm and filigree functional structures where exact adherence to and inexpensive reproduction of the shape are important for high piece numbers. A maximum TC is chiefly important for this use group. The linear coefficient of thermal expansion must be matched to the functional structures joined on. Because of the short length, the absolute differences in length are rather small at the temperature changes to be expected on the components.
(2) Less finely structured components having maximum dimensions in one direction of significantly more than 10 cm to more than 100 cm. In this context, moderate thermal conductivities are accepted. More important criteria here are the linear coefficient of thermal expansion matched to a functional material, the easy producibility of even complex structures, the good mechanical workability and proccessability and the marketable price of the components.

Components of field of use (1) are employed above all in the field of microelectronics, and components of field of use (2) in the field of high-performance electronics or high-performance electrical engineering, where high outputs over large areas must be conducted away by a functional element. Components of field of use (2) are employed, for example, as electronic power switches or as backing plates for sputter targets.

Backing plates for sputter targets must substantially fulfill two functions. On the one hand it must be possible to fix the actual sputter target securely on the backing plate, and on the other hand the heat arising during the sputtering operation must be conducted away from the sputter target. A large number of various materials which have quite different material properties are employed as sputter targets. The properties of the backing plate, in particular the coefficient of thermal expansion thereof, must be matched to the properties of the sputter target. Mo or W are therefore currently used as backing plates at a very low CTE of the sputter target (5 to approx. 10×10⁻⁶/K). Plates of extra-pure copper, aluminium or selected special materials (Al—Si, Al—SiC) are suitable for sputter targets having a significantly higher CTE (15 to 20×10⁻⁶/K). Particular difficulties result if large-area sputter targets of low CTE must be joined to the backing plate. Mechanical stresses can then already arise during fixing of the sputter target to the backing plate, e.g. by soldering, due to different coefficients of thermal expansion of the spatter target and backing plate, leading to damage on the sputter target directly or during sputtering.

Units of the backing plate and actual sputter target must be of a nature such that the join between the backing plate and the sputter target remains stable even under the extreme exposure to heat during the sputtering operation, and in particular no detachment or breaking of the sputter target occurs.

EP 1 331 283 A1 discloses a unit of a backing plate of a Cu—Cr or a Cu—Zn alloy and a tantalum or tungsten target in which the two units are joined to one another via a special intermediate layer of aluminium or an aluminium alloy. The intermediate layer must have a minimum thickness of 0.5 mm and allows the joining of materials of widely differing coefficients of thermal expansion. The backing plate and target material are joined together by means of hot isostatic pressing (HIP) in a so-called diffusion bond. The incorporation of the intermediate layer is involved and cannot be readily applied to other material combinations.

Stresses which arise due to the exposure to heat during the sputtering operation can be minimized by choosing the backing plate and target material such that they have very similar coefficients of thermal expansion. WO 92/17622 A1 describes corresponding units of backing plate and target material in which the coefficient of thermal expansion of the backing plate is established by a laminar build-up thereof. In addition to a base body of copper, the backing plate has a layer of molybdenum or a molybdenum alloy arranged on the base body. The target is in turn arranged on this layer. Such a carrier plate is suitable for target materials which have a coefficient of thermal expansion of about 10×10⁻⁶/K, for example silicon targets Such a backing plate is not suitable for other target materials. In addition, the production of the backing plates is very involved, since the upper layer must be joined firmly to the base body. Processes in which the pressure of an explosion wave is utilized, for example, are used. It is furthermore a disadvantage that the unit described now has an additional weak point, namely the join between the base body and upper layer, where detachment of the units from one another may occur during exposure to heat.

The object of the present invention is therefore to provide backing plates for sputter targets which are easy to produce, wherein the coefficient of thermal expansion can be established in a controlled maimer over a wide range. The backing plates should moreover have a high thermal conductivity, in order to allow efficient removal of the heat which arises during the sputtering operation.

It has now been found that the coefficient of thermal expansion can be established in a controlled manner over a wide range in a very simple manner if the backing plates are made of a composite material which comprises components of different coefficients of thermal expansion.

The invention therefore provides a backing plate for sputter targets, wherein the backing plate is made of a composite material which comprises 5 to 99 wt. % of at least one refractory metal and 95 to 1 wt. % of at least one further metallic component from the group consisting of Cu, Ag and Au.

The further metallic component from the group consisting of Cu, Ag and Au is distinguished in particular by a high thermal conductivity (320 to 425 W/m*K) and a high CTE (approx. 14 to 17×10⁻⁶/K).

The backing plates according to the invention are distinguished in particular in that the coefficient of thermal expansion can be established in a controlled manner over a wide range in a very simple manner by the choice of the components of the composite material and the particular contents. The production of the backing plate also influences its CTE to a minor extent. The backing plates furthermore have a high thermal conductivity, so that the heat formed during the sputtering operation can be reliably removed.

The backing plate is made of a composite material which combines the advantages of selected refractory metals (low CTE, non-alloyable or non-miscible with selected metals of high thermal conductivity) and metals of high thermal conductivity. Depending on tile requirements of the CTE, that is to say the peculiarities of the sputter target, a material combination which is suitable or to be aimed for is chosen taking into account material, production and cost criteria. Table 2 “Choice of materials for the best possible matching of the backing plate to the target material” shows the coefficients of thermal expansion of selected materials for sputter targets for the temperature range from room temperature (20° C.) to 300° C. Table 2 furthermore contains, in the columns W—Cu, Mo—Cu, Re—Cu and Ta—Cu, information on the copper content which the corresponding composite material must contain in order to have the desired coefficient of thermal expansion of the target material. Accordingly, it is possible e.g. to produce a backing plate for an MoSi₂ sputter target (CTE: 8.2×10⁻⁶/K) from a W—Cu composite material with 40 wt. % Cu, from an Mo—Cu composite material with 50 wt. % Cu, from an Re—Cu composite material with 21 wt. % Cu or a Ta—Cu composite material with 18 wt. % Cu.

TABLE 2
Choice of materials for the best possible matching
of the backing plate to the target material

| | | Composition of the composite material which has | | | |
|---|---|---|---|---|---|
| | | approximately the same CTE as the target | | | |
| | CTE | material to be attached | | | |
| Target | (RT-300° C.) | W—Cu | Mo—Cu | Re—Cu | Ta—Cu |
| material | 10⁻⁶/K | Cu in wt. % | Cu in wt. % | Cu in wt. % | Cu in wt. % |
| InSnO (ITO) | 8.3 | 40 | 51 | 21 | 19 |
| Y₂O₃ | 9.3 | 50 | 61 | 32 | 30 |
| Al₂O₃ | 6.8 | 27 | 31 | 6 | n.a. |
| MgO | 9 | 47 | 58 | 29 | 27 |
| WSi₂^{(S)} | 6.2 | 17 | 21 | n.a. | n.a. |
| Ta₅Si₃^{(S)} | 6-8^{(A)} | 28 | 35 | 9 | 2 |
| MoSi₂^{(S)} | 8.2 | 40 | 50 | 21 | 18 |
| TiSi₂^{(S)} | 10.5 | 60 | 70 | 44 | 44 |
| Ta₂N^{(S)} | 5.2 | 7 | n.a. | n.a. | n.a. |
| AlN^{(S)} | 4 | n.a. | n.a. | n.a. | n.a. |

^{(S)}G. V. Samsonov Handbook of High Temperature Materials No. 2, Properties Index, Plenum Press New York, 1964
^{(A)}Anisotropy of the coefficient of expansion requires particular measures in respect of the form of the target
n.a.: CTE not achievable with this material

As can be seen from Table 2, as a rule contents of copper of 7 to 70 wt. % are necessary in order to match the coefficient of thermal expansion of the composite material to the CTE of the usual target materials.

The backing plate according to the invention accordingly is preferably made of a composite material which comprises 10 to 95 wt. % of at least one refractory metal and 90 to 5 wt. % of at least one further metallic component from the group consisting of Cu, Ag and Au, particularly preferably of a composite material which comprises 15 to 95 wt. % of at least one refractory metal and 85 to 5 wt. % of at least one further metallic component from the group consisting of Cu, Ag and Au.

The refractory metal is preferably W and/or Mo, particularly preferably W or Mo.

Cu or a mixture of Cu and Ag and/or gold is preferably employed as the further metallic component. Particularly preferably, Cu or a mixture of Cu and not more than 5 wt. % Ag and/or gold, especially preferably Cu, is employed.

The backing plate is particularly preferably made of a composite material which comprises 15 to 95 wt. % Mo or W and 85 to 5 wt. % Cu.

The contents of refractory metal and ftirtlier metallic component, apart from unavoidable impurities, very particularly preferably add up to 100 wt. %.

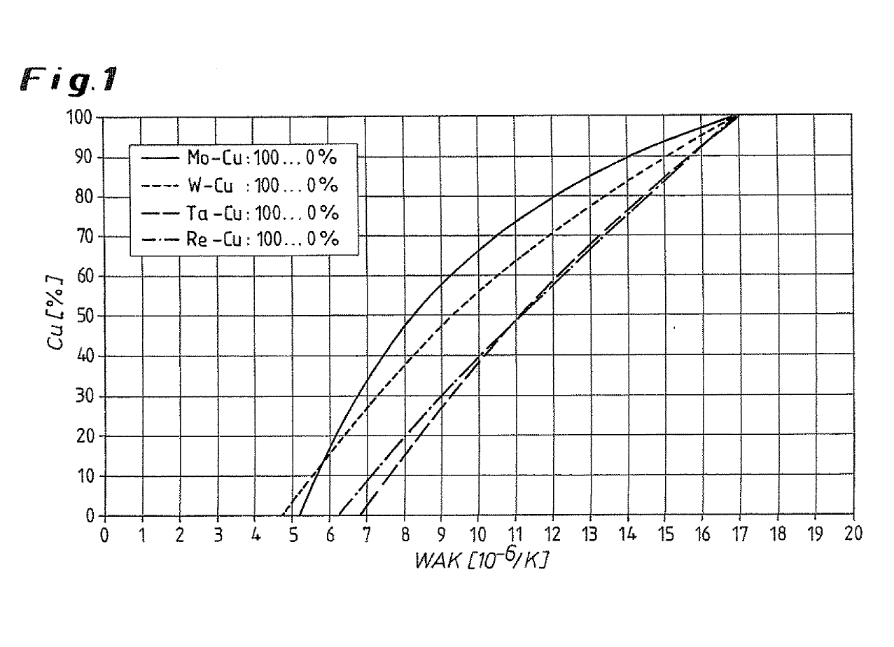

For the composite materials W—Cu, Mo—Cu, Re—Cu and Ta—Cu, the theoretical Cu contents in wt. % which the particular composite material must contain in order to have a desired CTE in the range from approx. 5 to 17×10⁻⁶/K can be read off from FIG. 1.

However, it is to be taken into account that this graph is based on a “volume-based” mixing rule which does not take into consideration the real structure of the composite material. In practice, the following production-related parameters which will influence the desired functional property (TC, CTE) of the composite material are also to be taken into account:
size and morphology of the constituents of the structure (refractory metal, further metallic component, pores);
arrangement of the constituents (continuous refractory metal network, continuous network of the further metallic component, pores in the refractory metal, pores in the further metallic component);
size of the interfaces between the refractory metal and further metallic component, to the pores in the further metallic component and to the pores in the refractory metal and
pore content.

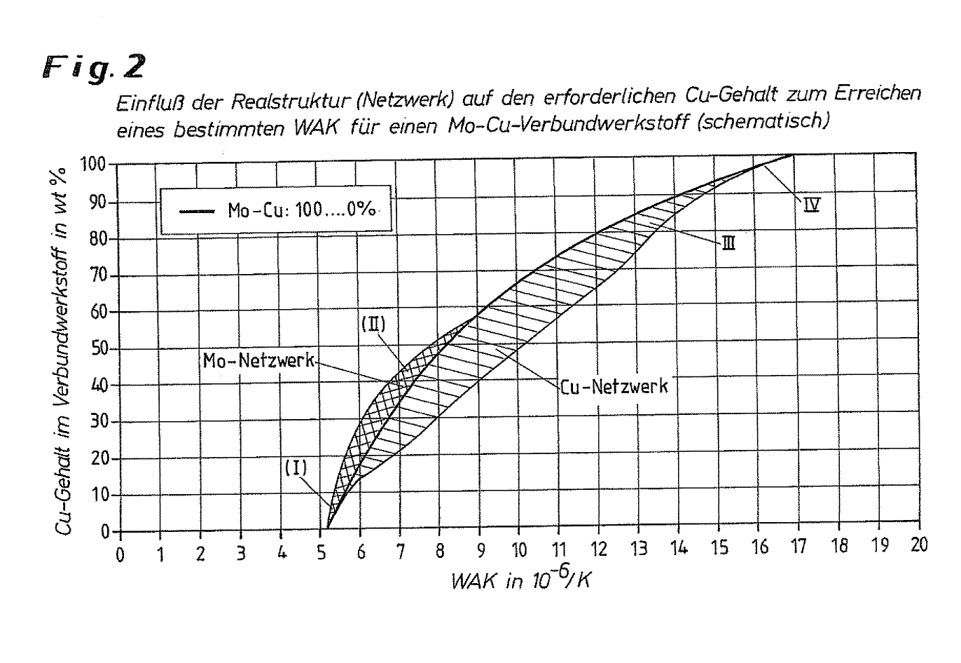

In the case of high contents of the refractory metal (99 to 50 vol. %), the formation of a closed network of tile refractory metal, in particular by infiltration processes, is possible. In this case, the high E modulus of the network means that the CTE increases “underproportionally” to the Cu content. This is shown in diagram form for an Mo—Cu composite material in FIG. 2, region (I). In the region of medium volume contents of the refractory metal (region II), both a refractory metal network and a network of the further metallic component can form. Which network forms can be controlled in a targeted manner via the nature of the production of the composite material (infiltration, processing of powder mixtures). At higher contents of further metallic component (in FIG. 2 Cu), an “overproportional” influence of Cu on the CTE can be expected (FIG. 2, region III). From region III, a closed Cu network at high volume contents of Cu can be expected, which, in respect of the resulting CTE, also (as in region II) overproportionally influences the CTE. Region IV stands for high Cu contents at which properties (TC, CTE) proportional to the Cu content are expected.

The range of the required Cu content (wt. %) in an Mo—Cu composite material in which the CTE aimed for is obtained can accordingly be determined with the aid of FIG. 2. The CTE achieved in the end is finally influenced by the production conditions, including the choice of raw materials. The necessary parameters which allow the production of a composite, material having a desired CTE can be determined by suitable preliminary experiments for choosing the composition of the material and for establishing the process parameters.

The ratio of thermal conductivity to linear coefficient of thermal expansion (TC/CTE ratio) can be used as a measure of a particular suitability as a material for a backing plate for sputter targets or uses with similar requirements (other heat sinks) of the material. High TC/CTE values (>approx. 23 (W/m*K)I(10⁻⁶/K) describe the ability of the material to transport large amounts of heat at a simultaneously low heat-related change in length (in the event of temperature differences occurring) of the component.

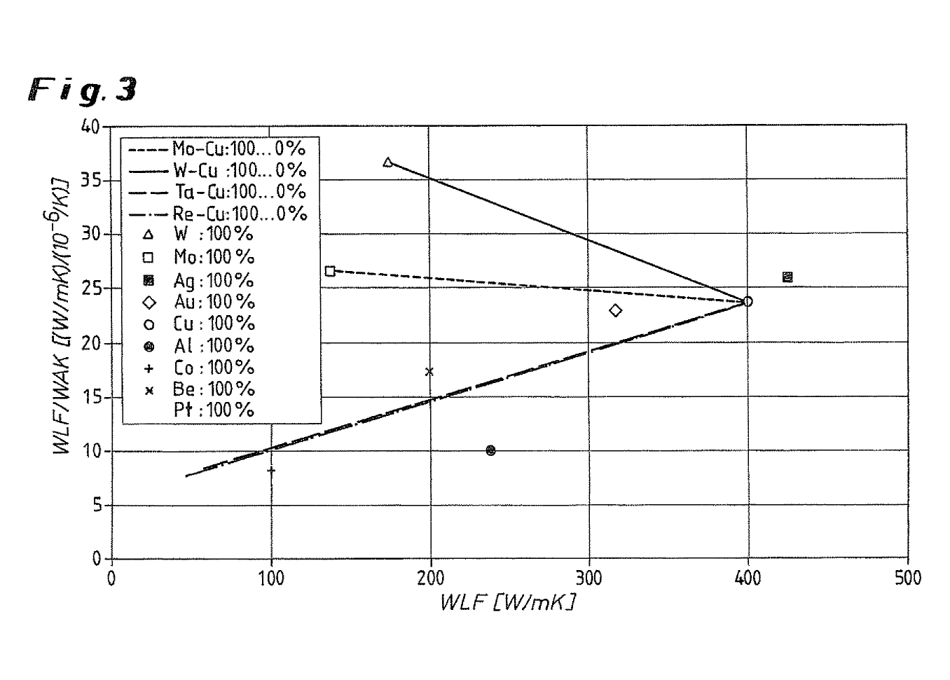

FIG. 3 shows the TC/CTE ratio as a function of the TC for various metals and the composite materials Mo—Cu, W—Cu, Ta—Cu and Re—Cu. As can be seen from FIG. 3, particularly high TC/CTE ratios can be achieved with the composite materials Mo—Cu and W—Cu.

The backing plates according to the invention preferably have a ratio of thermal conductivity to coefficient of thermal expansion in the temperature range from 20 to 300° C. of >23.8 (W/m*K)/(10⁻⁶/K), i.e. of >23.8×10⁻⁶ W/m.

The linear coefficient of thermal expansion (CTE) is a characteristic value of a solid which is determined in accordance with ASTM E228.

10⁻⁶/K is usually used as the unit of measure of the CTE of solids.

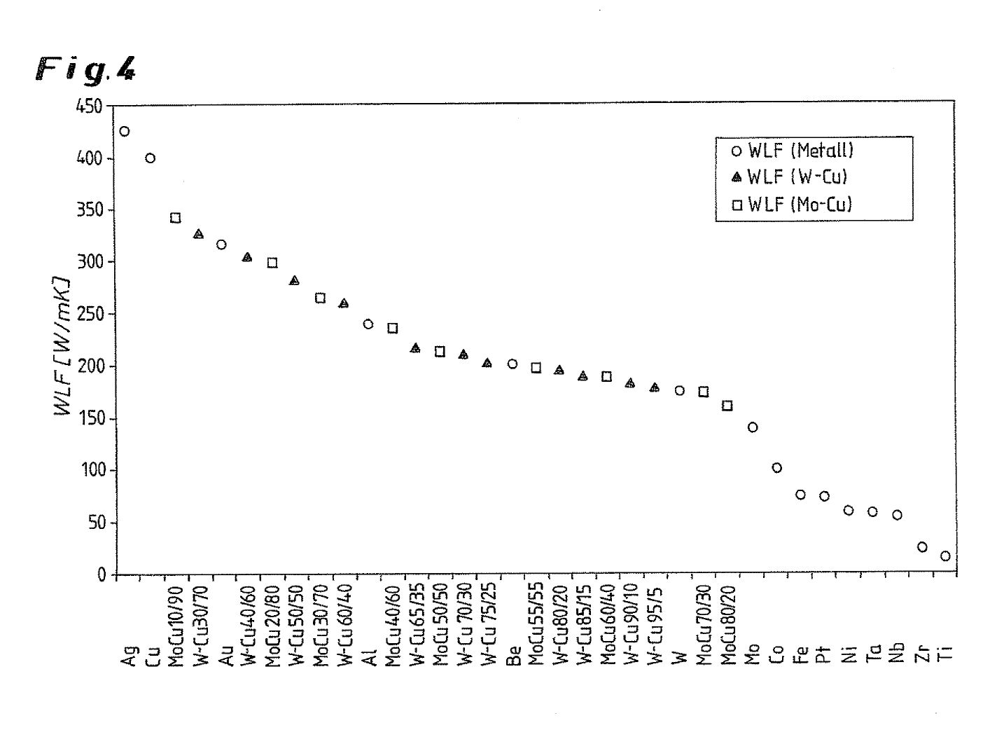

FIG. 4 shows the thermal conductivity (TC) of various metals in comparison with the thermal conductivity of the composite materials W—Cu and Mo—Cu of varying composition. It can be seen from FIG. 4, for example, that the Mo—Cu composite material MoCu 10/90, i.e. a composite material which comprises 10 wt. % Mo and 90 wt. % Cu, has a TC of almost 350 W/m*K.

The method ASTM E1225 is suitable for determination of the thermal conductivity (TC) up to 250 W/m*K. For determination of the thermal conductivity (TC) >250 W/m*K, a cylindrical measurement specimen (diameter: 200 mm, length: 40 mm) representative of the material and having a plane-parallel and exactly ground base and top surface is produced. Two bores (diameter: 1 mm, length: 100 mm) are introduced radially into this specimen at a longitudinal separation of 20 mm symmetrically to the length of the specimen. Two similar reference specimens are produced from massive extra-pure copper (99.99 %) having a certified TC, e.g. 400 W/m*K. The actual determination of the TC of the material specimen to be evaluated is carried out as a relative measurement between the two known Cu specimens and the unknown specimen. For this, the material specimen is clamped between the two reference specimens of copper. A heat source is arranged on the under-side of the arrangement and a cooling surface in good thermal contact with the copper reference specimens is arranged on the upper side. The arrangement produced in this way, comprising heat source, 1st reference specimen (R1), measurement specimen (M), 2nd reference specimen (E2) and cooled upper side, is introduced into a chamber with argon (99.999%). Thin, previously calibrated Ni—CrNi thermocouples (arm diameter: 0.2 mm) were inserted beforehand into the two bores of each disc to the centre of the disc and connected to a temperature-measuring apparatus. The arrangement is now heated up until a constant flow of heat from the heated to the cooled side has become established. The following 6 temperatures are determined for this state, temperature of the first reference specimen at the lower measurement point (T_{R1l}), temperature of the first reference specimen at the upper measurement point (T_{R2u}), temperature of the measurement specimen at the lower measurement point (T_{Ml}), temperature of the measurement specimen at the upper measurement point (T_{Mu}), temperature of the second reference specimen at the lower measurement point (T_{R2l}) and temperature of the second reference specimen at the upper measurement point (T_{R2u}). From these, the temperature differences: dT_{R1}=T_{R1u}−T_{R1l}, dT_{M}=T_{Mu}−T_{Ml} and dT_{R2}=TR_{R2u}−T_{R2l} are determined. The distances between the measurement points in each disc are exactly dx=20 mm. The thermal conductivity (λ), heat flow (I_{w}), specimen area (A) and temperature gradient in the specimen (dT/dx) are linked to one another by the following equation:
I_{w}λ*A*(dT/dx) (equation 1)

The following relationship therefore results for the reference specimens and the measurement specimen:
I^{R1}_{w}=λ_{R1}*A_{R1}*(dT_{R1}/dx) (equation 1a)
I^{M}_{w}=λ_{M}*A_{M}*(dT_{M}/dx) (equation 1b)
I^{R2}_{w}=λ_{R2}*A_{R2}*(dT_{R2}/dx) (equation 1c)

Providing that the areas (A) of the 3 specimens and flee distances (dx) between the thermocouples in each disc are identical and the heat flow (I^{M}_{w}) over the unknown specimen (M) is determined as I^{M}_{w}=(I^{R1}_{w}+I^{R2}_{w})/2, the following relationships are obtained, from which the desired thermal conductivity (λ_{M}) of the material can be determined:
λ^{R1}_{M}=λ_{R1}+(dT_{R1}/dT_{M}) or λ^{R2}_{M}=λ_{R2}+(dT_{R2}/dT_{M}) (equation 2)
and finally:
λ_{M}=(λ^{R1}_{M}λ^{R2}_{M})/2 (equation 3)

The TC (λ_{M}) determined in this manner corresponds to the TC at the average material temperature T_{M}=(T_{Mu}+T_{Ml})/2. For determination of the TC at other (for example higher) temperatures, the heating output is increased and/or the cooling output is reduced. A higher temperature is thereby obtained inside the arrangement, and using the abovementioned equations analogously, the TC at the new (higher temperature) is obtained.

W/m*K is as a rule used as the unit of measure of the thermal conductivity,

The ratio TC/CTE used in FIG. 3 is determined by simple division of the material characteristic values TC and CTE determined.

The geometry of the backing plates according to the invention can vary within wide limits and is substantially determined by the device into which the backing plate for the sputtering operation is to be employed. The backing plate can be constructed, for example, circular, oval, rectangular, square or also irregular in shape. The thickness is to be chosen such that the backing plate has a sufficient stability during attachment of the sputter target and during the sputtering operation.

Preferably, the backing plate has on the reverse side, ice, on the side on which the sputter target is not attached, channels through which a coolant can flow during the sputtering operation. Heat can be removed from the sputter target and the backing plate very efficiently in this manner.

The invention furthermore provides a process for the production of the backing plate according to the invention, wherein a composite powder comprising 5 to 99 wt. % of at least one refractory metal from the group consisting of Mo, W, Re and Ta and 95 to 1 wt. % of at least one further metallic component from the group consisting of Cu, Ag and Au is pressed axially or isostatically under a pressure of 50-1,000 MPa (500-10,000 bar) and then sintered.

Suitable sintering processes are vacuum sintering (0-0.1 MPa (0-1 bar)), pressure-less sintering (0.1-0.2 MPa (1-2 bar)), gas pressure sintering (0.2-10 MPa (2-100 bar)), HIP (gas pressure sintering under 10-400 Ma (100-4,000 bar)) and hot pressing. The sintering processes can be combined with one another into multi-stage sintering processes, e.g. phase 1: vacuum sintering, phase 2: HIP

A molybdenum-copper or tungsten-copper composite powder is preferably employed, particularly preferably a molybdenum-copper or tungsten-copper composite powder which has a metal primary size predominantly of <2 μm and an oxygen content of <0.8 wt. %. Such composite powders and their preparation are known from WO 02/16063 A2.

The process parameters to be adhered to during production of the backing plates according to the invention depend on the properties aimed for in tie composite material, and in particular on the desired content of refractory metals and further metallic components, e.g. Cu, in the composite material

By pressing and sintering of composite powders, in particular backing plates having low to medium contents of 1 to about 40 wt. % of further metallic component can be prepared.

In the case of the production of a backing plate from an Mo—Cu composite material, the sintering is preferably carried out under reducing conditions (e.g. hydrogen) at a temperature of 1,100 to 1,300° C., and particularly preferably 1,150 to 1,250° C. The sintering time is preferably 1 to 10 h, particularly preferably 2 to 5 h.

For example, a backing plate can be obtained from an Mo—Cu composite material having a copper content of 30 wt. % by cold isostatic pressing (CIP) of an Mo—Cu composite powder in a rubber mould under 200 MPa (2,000 bar), green working (grinding, turning) to the final dimensions plus sintering shrinkage, heating up at 5 K/min (hydrogen-containing atmosphere) to 1,050° C., holding time at 1,050° C. of 30 min, further heating at 2 K/min to 1,110 to 1,150° C., holding time of 4 h at the chosen temperature and cooling to RT at 5 K/min. An Mo—Cu composite material having the following properties is obtained: density >96% of the theoretical density (TD) (>9.4 g/cm³), CTE: approx. 8(±1)×10⁻⁶/K, TC: 170-200 W/m*K, TC/CTE =22-30 (W/m*K)/(10⁻⁶/K). The exact physical characteristic values depend on the properties of the powders used, the processing and the thermal treatment during sintering or, tie heat treatment. The desired CTE can be established by variation within the framework of the abovementioned window of parameters, and the TC results in the range described.

W—Cu backing plates, in particular those comprising 1 to about 30 wt. % Cu, are produced in an analogous manner using corresponding composite powders. In contrast to the Mo—Cu material, the W—Cu system requires a higher sintering temperature. Sintering temperatures Lip to approx. 1,450° C. and sintering times of approx. 4 h are required, depending on the Cu content.

In the case of the production of a backing plate from a W—Cu composite material, sintering is therefore preferably carried out under reducing conditions (e.g. hydrogen) at a temperature of 1,100 to 1,500° C., and particularly preferably 1,200 to 1,450° C. The sintering time is preferably 0.5 to 10 h, particularly preferably 1 to 5 h.

Backing plates from materials having high contents of refractory metals (>60 wt. %) and the lowest possible CTE (5 to 6×10⁻⁶/K) are preferably produced via infiltration of a skeleton of a refractory metal with the desired further metallic component, preferably copper.

The invention therefore furthermore provides a process for the production of backing plates according to the invention having a content of refractory metal of >60 wt. %, wherein a sintered body of a refractory metal from the group consisting of Mo, W, Re and Ta is first produced and this is then infiltrated with 1 to 40 wt. % of a further metallic component from the group consisting of Cu, Ag and Au.

For production of the sintered body of the refractory metal, a refractory metal powder is first pressed to a sheet and the pressed body is then sintered at a temperature of at least 1,700° C. under hydrogen. This sintered body is then infiltrated in a second step with a melt of the further metallic component, preferably a copper melt, at significantly above the melting point of the further metallic component, e.g., at 1,200° C. The open pores of the refractory metal skeleton are filled completely with the further metallic component in this manner, and the body formed changes its external dimensions only slightly, so that—provided the skeleton is of completely open porosity—the composite material can be roughly predetermined in its properties in respect of content of further metallic component and therefore TO and CTE. The precise process parameters for establishing a particular CTE for a specific composition of the starting powder can be determined by simple preliminary experiments. The physical properties, for example CTE, TC, density and E modulus of the composite material, result according to the real structure of the composite material and the primary physical properties of the constituents of the structure (refractory metal, further metallic component, pores).

Backing plates of composite materials in which, because of a desired high CTE of >approx. 11×10⁻⁶/K, the content of further metallic component, e.g. the content of Cu, must be very high (for example 70 to 90 wt. %), can be produced very easily via pressing and forming of suitable starting powders. By mixing composite powders having appropriately high contents of further metallic component or simple mixtures of powders of the further metallic component and refractory metal powders, pressing and compacting to >95% of tie theoretical density (TD) by a forming step, such as, for example, forging, rolling and the like, a backing plate having the desired properties is obtained. However, it is also to be taken into account here that the establishing of the properties, for example CTE, TC and E modulus, depends on the “real structure” of the material and therefore on its concrete production. If forming processes are used, annealing below the melting point of the further metallic component is appropriate, if required, in order to avoid negative influences of cold compaction on the functional properties.

The invention furthermore provides units which comprise a sputter target and a backing plate according to the invention.

Preferred target materials are those which have a CTE which is in the range from 5 to 16×10⁻⁶/K and which moreover, because of their mechanical strength properties (breaking properties, brittleness) require a backing plate which largely prevents the development of mechanical stresses during fixing (bonding) and/or during use in a sputtering installation. Some examples are mentioned in Table 2. However, the choice could be extended almost as desired, since the diversity of materials for sputter targets is very wide.

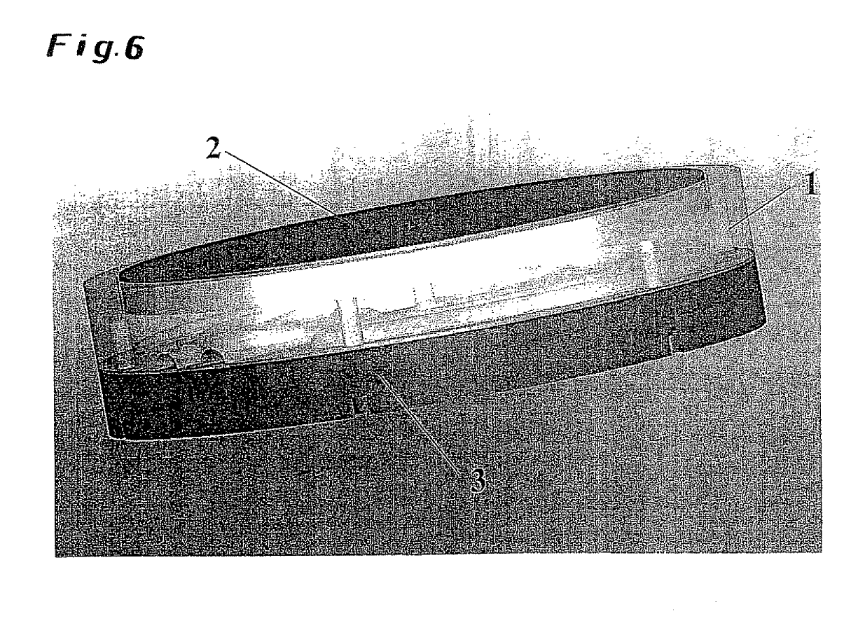

FIG. 6 shows a unit according to the invention having a backing plate (1) according to the invention, on to which the sputter target (2) is attached. The unit is in turn arranged on a fixing plate (3), which can be made e.g. of copper. The channels detectable on the under-side of the backing plate serve to feed in and remove a cooling medium during the sputtering operation. The backing plate can have one or more grooves for accommodating sealing rings or tapes, e.g. in order to seal off the backing plate (2)) from the fixing plate (3) (not shown). A low-melting solder based on tin, indium, lead or silver is often used to fix a sputter target to the backing plate. If the wetting of the sputter target and/or the backing plate is inadequate, it is advisable to apply a twin intermediate layer of Cu, on which the solder then allows adequate wetting and therefore better promotion of adhesion between the sputter target and backing plate.

The invention is explained in more detail below with the aid of examples, wherein the examples are intended to facilitate the understanding of the principle according to the invention and are not to be understood as a limitation thereof.

### EXAMPLES

Unless stated otherwise, the percent data are percent by weights.

### Example 1

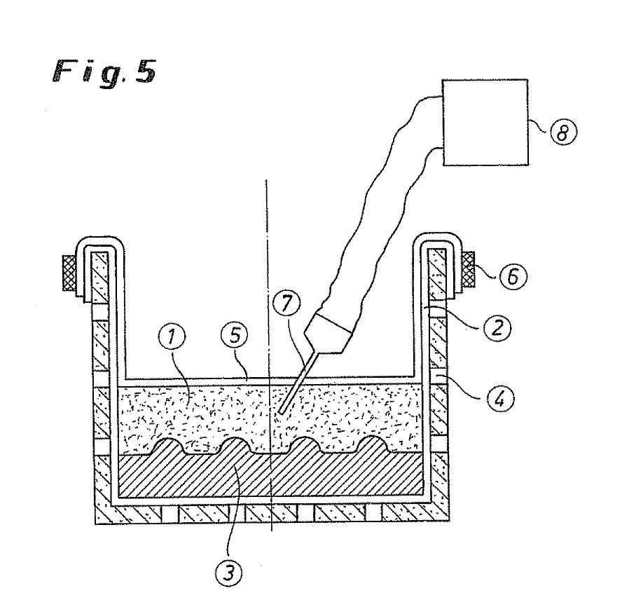

A backing plate according to the invention was produced in a device such as is shown in diagram form in FIG. 5. A composite powder mixture (1) which comprised W to the extent of 80 wt. % and Cu to the extent of 20 wt. % was introduced into a rubber mould (2)), while shaking. On the base of the rubber mould (2)) was a profiled metal body (3) polished on the surface. The rubber mould was held by a support cage (4). The rubber mould (2)) was laid around the upper edge of the support cage (4). Thereafter, the surface of the powder bulk was closed with a second rubber mould which serves as a lid (5). This was folded around the support cage (4) and the rubber mould (2)) in order to form a tightly closed-off space for the powder to be pressed. For fixing the arrangement, a securing tape (6) was fixed such that the filled rubber mould, comprising the rubber mould (1) and lid (5), was sealed off. Thereafter, the rubber mould was evacuated by inserting a cannula (7) connected to a vacuum pump (8). After a period of 10 min, the cannula (7) was drawn out of the rubber mould (5). The puncture hole of the cannula thereby closed automatically. The rubber mould prepared in this way was introduced into a hydrostatic press (CIP), which is not shown. The powder mixture was compacted to a pressed density of 9.3 g/cm³ by application of a pressure of 4,000 bar. The non-deformable profiled metal body (3) polished on the surface acts as an embossing die. Due to the choice of the profile, the nature of the surface and the resiliency of the pressed powder, the powder compact and the profiled metal body (3) polished on the surface became detached from one another during the slow decrease in the hydrostatic pressing pressure. After opening of the rubber mould, it was possible to remove the pressed body. The pressed body formed in this way had a well-moulded under-side, but less exactly shaped edge regions which were formed in direct contact with the rubber mould during the pressing operation. The pressed body was therefore subjected to mechanical machining. A pressed powder shaped body having a smooth upper side and a cylindrical edge region was formed in this manner.

This pressed powder shaped body was heated up to a temperature of 1,450° C. in a sintering oven under a reducing hydrogen atmosphere. After a holding time of 2 h, the temperature was lowered to room temperature and the sintered body was removed from the oven. Due to a linear sintering shrinkage of about 15%, a sintered body which was reduced in size uniformly in all spatial direction compared with the pressed powder shaped body was formed. This sintered body had a density of 15.1 g/cm³, a linear coefficient of thermal expansion of 6×10⁻⁶/K and a thermal conductivity of 185 W/m*K. For further processing of the sintered body to a backing plate, the two flat functional surfaces and the cylindrical past were machined to the final dimensions, the embossed cool stricture requiring no working. Threads were furthermore attached, which allow a later fixing to a base plate which renders possible fixing of the cool structure to the sputtering installation.

A ceramic WSi₂ target was attached to the W—Cu backing plate produced in this way. This was achieved by soldering the target on to the flat, non-profiled side of the backing plate. Since the ceramic WSi₂ target chosen has a linear coefficient of thermal expansion in the temperature range from RT to 300° C. of 6 to 6.5×10⁻⁶/K, after the surfaces to be soldered had been pretreated in a soldering oven under a suitable atmosphere it was possible to produce a material-locking join to the backing plate with a high adhesive strength and therefore a high heat removal capacity.

In the case where if other sputter targets or backing plates of other material compositions are employed pretreatment of the surfaces to be joined does not allow adequate wetting of the solder material, one or both surfaces are provided with a thin Cu layer applied via a coating process (0.001-100 μm), for which there are no wetting problems when the relevant solder materials are used. A joining of the sputter target to the backing plate which is not exposed to a critical mechanical stress while this join is produced nor at a later point in time in the sputtering installation is formed in this manner. This prevents the brittle target material from being damaged (cracking) or becoming detached from the backing plate due to stresses, as a result of which the cooling would be drastically reduced locally, which can lead to increased stresses up to falling of the sputter target from the backing plate. As a result, the sputtering installation and the components to be constructed may be destroyed.

### Example 2

Pure molybdenum powder (grain size <10 μm ) was pressed as described in Example 1. The upper side and the circumference of the compact were ground flat and, respectively, cylindrical The pressed body produced in this way was sintered for 4 h at a temperature of 1,700° C. under a reducing gas atmosphere. Thereafter, the sintered body was removed and the density ρ_{PB}=m_{PB}/V_{PB} was determined by measuring the volume (V_{PB}) and measurement of the mass (m_{PB}). This was 4.5 g/cm³. The pore volume (V_{Por}) can be determined from the density ρ_{PB} of the sintered body and the density of pure molybdenum (ρ_{Mn}=10.2 g/cm³) from V_{Por}=100×ρ_{PB}/ρ_{Mo}. The pore volume was 44.1%. With the aid of the pore volume determined and the dimensions of the sintered body, the amount of copper which is required to fill up the pore volume completely, i.e. to infiltrate the sintered body completely, can be determined. At a mass of the Mo skeleton sintered body of 1 kg (volume: 222 cm³), a pore volume of 98 cm³ exists, for which 877 g copper are required (ρ_{Cu}=8.96 g/cm³) in order to infiltrate the sintered body completely. In this case, an infiltration material Mo—Cu (53% Mo/47% Cu) which has a CTE of approx. 8×10⁻⁶/K would be present. The CTE is typically established at an exact value by experiments and measurement of the actual coefficient of expansion. Because the effect of the Mo skeleton on the CTE cannot be described exactly, experiments are necessary for reliably establishing a desired CTE. Final working of the functional surfaces is carried out by turning or grinding.

### Example 3

For production of a backing plate according to the invention, a suitable powder mixture can also be subjected to a forming process. For this, for example, a mixture of 10 kg Mo powder, (<10 μm) and 8.77 kg Cu powder (<50 μm) is subjected to hydrostatic pressing under a pressure 200 MPa (2,000 bar) in a rectangular evacuated rubber mould (30 cm×50 cm×6 cm−9 dm³) which has been closed air-tight. The density thereafter would be 5.1 g/cm³. Compaction to 8.4 g/cm³ is carried out by forming in a forging press. Such an Mo—Cu composite material having a Cu content of 47 wt. % has a continuous Cu network. A CTE of about 10×10⁻⁶/K is to be expected. The CTE is typically established at an exact value by experiments and measurement of the actual coefficient of expansion. Because the effect of the Cu network on the CTE cannot be described exactly, experiments are necessary for reliably establishing the CTE. Final working of the functional surfaces is carried out by turning or grinding.

1. Backing plate for sputter targets, characterized in that the backing plate is made of a composite material which comprises 5 to 99 wt. % of at least one refractory metal from the group consisting of Mo, W, Re and Ta and 95 to 1 wt. % of at least one further metallic component from the group consisting of Cu, Ag and Au.

2. Backing plate according to claim 1, characterized in that the refractory metal is W and/or Mo.

3. Backing plate according to claim 1, wherein the further metallic component is Cu.

4. Backing plate according to claim 1, wherein the composite material comprises 15 to 95 wt. % Mo or W and 85 to 5 wt. % Cu.

5. Backing plate according to claim 1 wherein the backing plate has a ratio of thermal conductivity to coefficient of thermal expansion in the temperature range from 20 to 300° C. of >23.8×10⁻⁶ W/m.

6. A process for the production of the backing plate according to claim 1, which comprises pressing a composite powder comprising 99 to 5 wt. % of at least one refractory metal from the group consisting of Mo, W, Re and Ta and 1 to 95 wt. % of at least one further metallic component from the group consisting of Cu, Ag and Au under a pressure of at least 50 MPa and then sintered.

7. The process according to claim 6, characterized in that a molybdenum-copper or tungsten-copper composite powder which has a metal primary size predominantly of <2 μm and an oxygen content of <0.8 wt. % is employed.

8. The process for the production of a backing plate according to claim 1, wherein the content of refractory metal is >60 wt. %, which comprises first producing a sintered body of at least one refractory metal from the group consisting of Mo, W, Re and Ta and this is then infiltrated with 1 to 40 wt. % of at least one further metallic component from the group consisting of Cu, Ag and Au.

9. A unit comprising a sputter target and a backing according to claim 1.

10. The unit according to claim 9, characterized in that the sputter target and the backing plate are joined to one another by means of a binding layer.
